(19) United States
(12) Patent Application Publication
(10) Pub. No.: US 2004/0132306 A1
(43) Pub. Date: Jul. 8, 2004

(54) Method using multi-component colloidal abrasives for CMP processing of semiconductor and optical materials

(76) Inventors: Robert A. Bellman, Painted Post, NY (US); Robert Sabia, Corning, NY (US); Ljerka Ukrainczyk, Painted Post, NY (US); J. Marc Whalen, Corning, NY (US)

Correspondence Address: CORNING INCORPORATED, SP-TI-3-1, CORNING, NY, 14831

(21) Appl. No.: 10/722,769

(22) Filed: Nov. 26, 2003

Related U.S. Application Data
(60) Provisional application No. 60/432,076, filed on Dec. 9, 2002.

(51) Int. Cl. C09K 3/14; B24D 3/02; H01L 21/302; H01L 21/461

(52) U.S. Cl. 438/690

(57) ABSTRACT

A method is provide for using abrasive colloidal particles having multi-component composition comprising mixed 1) metal or metalloid oxides, 2) oxyfluorides, or 3) oxynitrides, each grouping (1, 2, or 3) individually alone or in combination thereof, in a chemical-mechanical manufacturing process for planarizing or polishing metal, semiconductor, dielectric, glass, polymer, optical, and ceramic materials. The particles exhibit a modified surface chemistry performance and have an isoelectric point (pH_{IEP}) greater than the pH of the dispersed particles in solution, and with a stabilized particle dispersion at pH values of interest for CMP operations. The composition of the multi-component particles may be adjusted as desired, in regard to their chemical or physical properties such as surface chemistry, hardness, solubility, or degree of compatibility with the workpiece material being planarized or polished. Also provided is a chemical-mechanical planarization slurry mixture incorporating such multi-component particles and with a solution chemistry that enhances the CMP effects by in-part adjusting the pH of the solution away from the pH_{IEP} of the media to maximize dispersion.

### CROSS-REFERENCE TO RELATED APPLICATIONS

U.S. Provisional Application No. 60/432,076, filed Dec. 9, 2002, which claims the benefit of U.S. Provisonal Application No. 60/167,121, filed on Nov. 23, 1999, and International Application WO 01/39260, filed on 22 Nov. 2000, in the names of Darcangelo et al., the contents of both are herein incorporated by reference.

### FIELD OF THE INVENTION

The present invention relates in part to the formation and use of colloidal abrasives. In particular, the present invention relates to mixed-oxide and nitride, and doped-silicate colloidal particles and a method for their use in chemical-mechanical planarizing and polishing of semiconductor and/or optical materials.

### BACKGROUND OF THE INVENTION

In the semiconductor, microelectronic industry, a process for manufacturing integrated circuit devices comprises polishing a surface of a semiconductor wafer using chemical and mechanical components, such as abrasives supplied between the surfaces of the wafer and a polishing pad. This process is commonly known as chemical-mechanical planarization (CMP). The use of abrasive materials, such as colloidal alumina, ceria, and silica, is considered to be state-of-the-art for CMP.

CMP has developed into an integral component of the manufacture and yield of cost effective semiconductor products. Various semiconductor integrated circuit layers are stacked on top of a semiconductor wafer or substrate. The stacked layers are deposited and formed on the semiconductor substrate so that electrical connections can be made to the devices incorporated in the semiconductor substrate wafer and the devices can perform their intended functions (such as for computations and computer processing). In general, a CMP apparatus for planarizing surface of the wafer includes a polishing head for supporting and pressing the wafer, a polishing platen rotatively operating and having a polishing pad, a slurry supplying device, and a conditioner for conditioning the polishing pad.

When the CMP apparatus performs the polishing process, the surface of the wafer being polished must be uniformly polished throughout. Hence, the polishing pressure applied to a respective region of the wafer, the amount of slurry, and the condition of the polishing pad, which come in contact with the wafer, must be regularly controlled. Typically in the CMP process, particles suspended in a solution act to mechanically abrade a workpiece surface, as chemicals in the solution react with the surface to either increase or decrease the removal of deposited materials as necessary. That is, dissolution for maximizing removal or passivation for minimizing removal, so as to provide flat, planar surfaces for the stacking of circuit layers and formation of electrical connections.

The persistent trend towards miniaturization in the semiconductor industry has led to ever-higher requirements in the chemical-mechanical polishing of oxide and metal layers. The aim of polishing is a rapid, precise removal of the surface without generating scratches, with the highest possible selectivity of the polishing agent towards the various layers required for building up an integrated circuit. Attempts are made to meet these higher demands on the polishing agent in part by employing physical mixtures of polishing particles for a polishing task, in order thus to combine the particular advantages of the mixture partners.

Although uniform particles are present in chemical mixtures of polishing particles, the known preparation processes and the availability of the starting materials limit the combination possibilities. A process for the preparation of mixed oxides is described, for example, in EP-A-1048617. In a pyrogenic process, an SiCl₄/AlCl₃ mixture is brought together in an oxygen/hydrogen flame and a mixed oxide of silicon dioxide and aluminum oxide is obtained in a hydrolysis step. Uniform is to be understood as meaning that a mixed-oxide particle consists of the two molecular species SiO₂ and Al₂O₃.

The doped, pyrogenic oxides described in DE-A-196 50 500 extend the range of abrasive particles for chemical-mechanical polishing. The doping component, which is distributed in the entire particle, changes the structure and the properties of the particular particle and therefore the polishing properties, such as rate of removal of material and selectivity. Polishing selectivity, however, is not sufficient for uses in chemical-mechanical polishing of very thin layers.

Furthermore, since the abrasive particles of in CMP slurry can effect the slurry chemistry and its use, the slurry solution must be adjusted to a pH level that will allow for attainment of the best surface finish and the solution must be stabilized from agglomeration and pH shifts during storage. For conventional colloidal silica abrasives designed for microelectronic applications, buffers solutions using mixtures of various bases and salts are incorporated for stabilization anywhere between a pH value of ˜5-12. For instance, a buffered solution adjustment to pH level of ˜10-11 is most common for colloidal silica solutions stabilized for single-crystal silicon polishing. Although silica particles in buffer solution systems with alkaline pH values are fairly stable, they do not necessarily produce optimal results for CMP operations that require acidic conditions. This disadvantage of current CMP approaches arises because often the parameters that are important for the polishing operation, for example, the particle sizes or the behavior of the polishing particles at various pH ranges, do not match one another. This means that no stable dispersions for chemical-mechanical polishing can be obtained, and particles tend to agglomerate.

Currently, the selection of abrasive particles is relatively limited to the materials mentioned above. This means that one is limited in the flexibility or degree to which one can manipulate the surface chemistry or hardness of abrasive particles. Silica and alumina colloids are formed through various techniques and typically require expensive precursor materials in order to ensure the highest purity products.

Since the application of colloidal suspensions for polishing and planarizing advanced materials has become a critical aspect of final part formation for semiconductor substrates and optical-quality surfaces, a need exists for a new method of using abrasive, colloidal particles having mixed-oxide, oxyfluoride, or oxynitride components. The colloidal particles should have properties that can be tailored to meet the particular requirements of a variety of material surfaces and/or CMP applications at lower, acidic pH values with stable dispersion performance and minimal particle agglomeration.

### SUMMARY OF THE INVENTION

The present invention, in part, relates to the formulation and use of mixed-oxide, oxyfluoride and oxynitride abrasive colloidal particles suited for planarizing and polishing applications. In one aspect, the present invention describes the application of multi-component colloidal particles that have compositions which may be adjusted as desired, in regard to their chemical or physical properties such as surface chemistry, hardness, solubility, or degree of compatibility with the workpiece material being planarized or polished. When used in a CMP slurry, the particles' multi-component composition is believed to generate an advantageous effect for better dispersion in solution. This effect shifts the multi-component particles' isoelectric point (i.e., point of zero charge on the particles), such that the pH_{IEP} can be raised or lowered as desired. This feature can reduce the likelihood of agglomeration at operational pH values, thus enhancing the efficiency and operation of CMP processes, even at smaller particle sizes.

Using various techniques, such as flame hydrolysis, chemical vapor deposition, or sol-gel processing, the abrasive colloidal material can be formed from a variety of components, including mixed-oxides or silicate-based glasses, as well as non-glass-forming constituents. The resulting particles have either a spherical, near-spherical, elongated, or amorphous morphology.

The multi-component particles can be employed in both aqueous and non-aqueous suspensions, such as ethylene glycol, glycine, or alcohol. In aqueous environments, solution chemistry can be manipulated to enhance the CMP effects by in-part adjusting the pH of the solution away from the pH_{IEP} of the media to maximize dispersion. In non-aqueous environments, the particles can be used strictly for abrasion, where the particle hardness dictates the planarization or polishing effect. Abrasive compositions can be selected to maximize removal rate, while limiting the formation of surface defects such as scratches. Particles as such may be used for polishing softer, defect-prone glasses or crystals.

The invention further comprises either a semiconductor or optical materials processing CMP slurry solution with abrasive multi-component colloidal particles dispersed in a semiconductor processing chemical-mechanical slurry solvent. Chemical-mechanical planarizing slurries according to the invention preferably provide beneficial slurry stability with avoidance of agglomeration and gellation. The multi-component particles in the slurry are redispersable without agglomeration or gellation after stagnant settling times greater than 24 hours.

The present invention also pertains to a chemical-mechanical manufacturing process for planarizing or polishing metal, semiconductor, dielectric, glass, polymer, optical, and ceramic materials. The process comprises: providing a workpiece having a non-planarized workpiece surface; providing a chemical-mechanical planarizing colloidal slurry, said slurry comprising non-agglomerated multi-component particles of a mixed-oxide, oxyfluoride, or oxynitride composition, each particle exhibiting a modified surface chemistry performance and having an isoelectric point (pH_{IEP}) greater than or equal to about 5-6 with a stabilized particle dispersion at pH values of interest for CMP operations; and abrading a surface of said workpiece with the multi-component particles.

The invention further includes a method of making a semiconductor processing chemical-mechanical planarizing slurry. The method includes providing a collection of multi-component particles having either a solid spherical, near-spherical, or amorphous morphology and a semiconductor processing chemical-mechanical pre-slurry solvent and dispersing the particulate abrasive agent colloidal particles in the pre-slurry solvent to form a semiconductor processing chemical-mechanical planarizing slurry solution.

Additional features and advantages of the present invention will be disclosed in the following detailed description. It is understood that both the foregoing summary and the following detailed description and examples are merely representative of the invention, and are intended to provide an overview for understanding the invention as claimed.

### BRIEF DESCRIPTION OF DRAWINGS

FIG. 1 shows a graph of the difference in surface charge behavior between SiO₂ and TiO₂—SiO₂ particles with identical surface area.

FIG. 2 shows a graph of difference in surface charge behavior for SiO₂ particles with varying surface area (i.e., higher surface area indicates smaller particle size). At the isoelectric point (IEP), the abrasive particles exhibit a decrease in agglomeration as a function of particle surface area. Particles with higher surface area exhibited worse dispersion performance at low pH values than particles with lower surface area, which indicates that particles with low surface area are more desirable for microelectronics polishing.

FIG. 3 is a graph showing a comparison of the performance of SiO₂ and multi-component silicate particles of identical particle size. The graph illustrates a principle that multi-component particles can have superior dispersion performance at low pH values, and may be tailored to have different isoelectric points. As depicted, the isoelectric point of the multi-component particles is displaced toward a less acidic pH value for better particle dispersion and improved performance in planarization and polishing at an acidic pH value, as required for particular CMP applications.

### DETAILED DESCRIPTION OF THE INVENTION

Dispersion of particles in acidic environments is of specific interest to the semiconductor industry for chemical-mechanical planarization (CMP), where slurry formulations are typically adjusted to pH ˜2-7 for the planarization of metal interconnecting layers. (“Chemical Mechanical Planarization of Microelectronic Materials,” J. M. Steigerwald, S. P. Murarka, R. L. Gutmann, John Wiley and Sons, 1997; C. J. Brinker, J. Non-Crystalline Solids, 100 (1988) 31; L. M. Cook, J. Non-Crystalline Solids, 120 (1990) 152.) Traditionally for CMP processing, a stable dispersion of colloidal silica particles was difficult to obtain at acidic pH values. Most often, the colloidal particles agglomerated, with an associated degradation in their efficiency as fine abrasives. To overcome this problem, various approaches have been proposed. Some, for instance in EP-A-1048617, have suggested using mixed-oxide particles consisting of two molecular species SiO₂ and Al₂O₃. Others, for example in U.S. patent application Ser. No. 2002/0177311 A1, have put forward using oxide particles with a core, a doping component distributed in the core, and an outer shell surrounding the core, wherein the core, doping and shell are of different chemical compositions. These solutions, however, have not addressed the underlying cause of the problem and, hence, have not being able to solve the problem systematically.

A major concern of the problem pertains to the surface chemistry of silica in aqueous systems, especially surface charge and reactivity. Like other oxide surfaces in aqueous solutions, the silica surface is OH-terminated, amphoteric, and has a pH dependent surface charge. Surface charge and acidity of oxides are usually measured using acid-base titration of suspended oxide particles in solution. The mean surface charge (Q), defined as the portion of the surface charge due strictly to [OH⁻] and [H⁺], can be calculated in terms of surface species per gram (mol/g). Oxide surfaces can acquire either a positive or negative charge by association or dissociation of protons. As the inventors discussed in J. Non-Crystalline Solids, 277 (2000) 1-9, or in J. Material Research, Vol. 17, No. 7, July 2002, or in International Application WO 01/39260, contents of which are incorporated herein by reference, the acid-base behavior of an oxide surface is typically described by pKₐ values (i.e., dissociation constants).

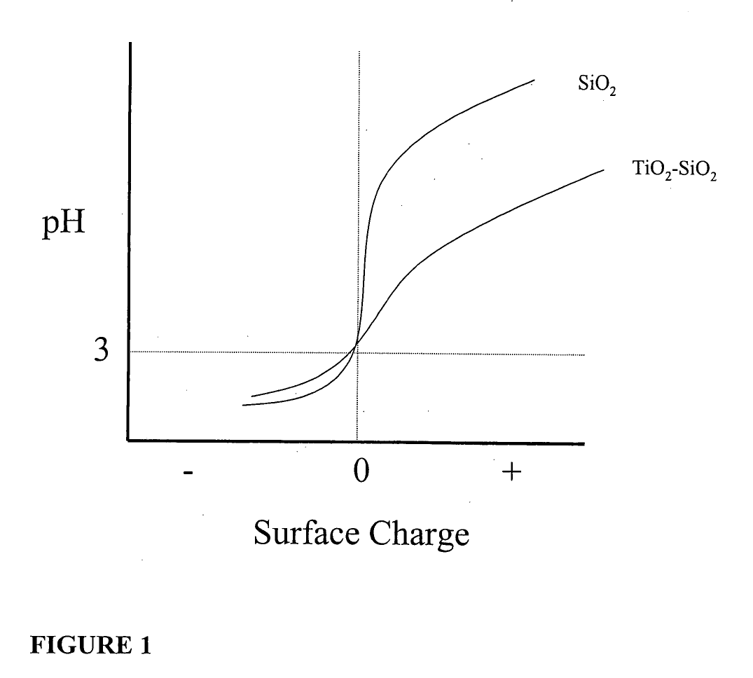

Surface chemistry is greatly affected by the composition and method of particle preparation. Addition of other metal or metalloid ions to silica soot can alter the surface acidity and surface charge of the resulting silicate particles, FIG. 1 shows a graph of the difference in surface charge behavior between SiO₂ and TiO₂—SiO₂ particles of identical surface area, prepared by flame hydrolysis. TiO₂—SiO₂ particles are softer and more easily dispersible than pure SiO₂ soot. (R. Sabia et al., J. Non-Crystalline Solids, 277 (2000) 1-9.)

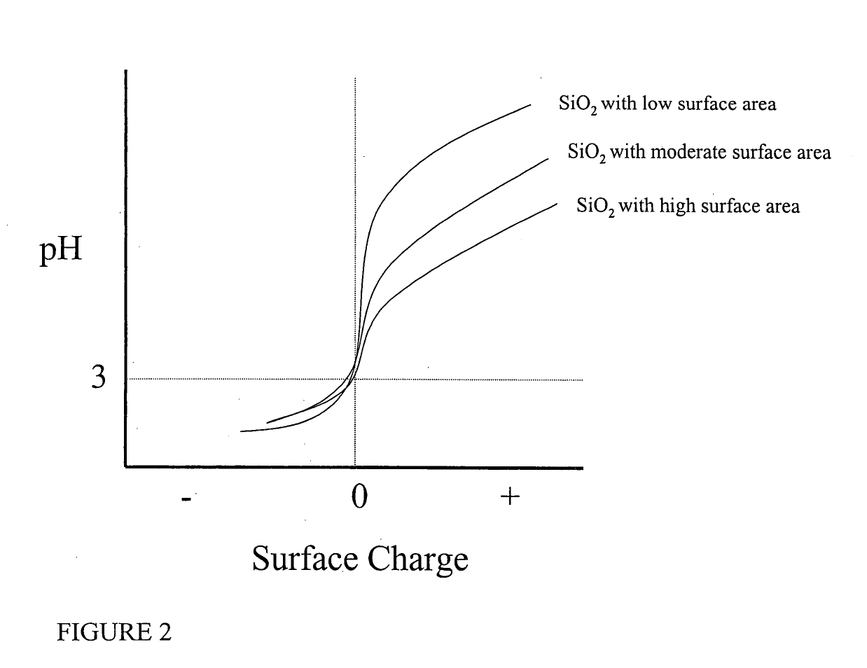

FIG. 2 shows a graph of difference in surface charge behavior for SiO₂ particles with varying surface area. Particles with lower surface area tended to exhibit worse dispersion performance at low pH values than particles with higher surface area, which indicates that particles with high surface area (i.e., smaller particle size) are more desirable for microelectronics polishing. At the isoelectric point (IEP), the abrasive particles with higher surface area tend to exhibit a decrease in agglomeration.

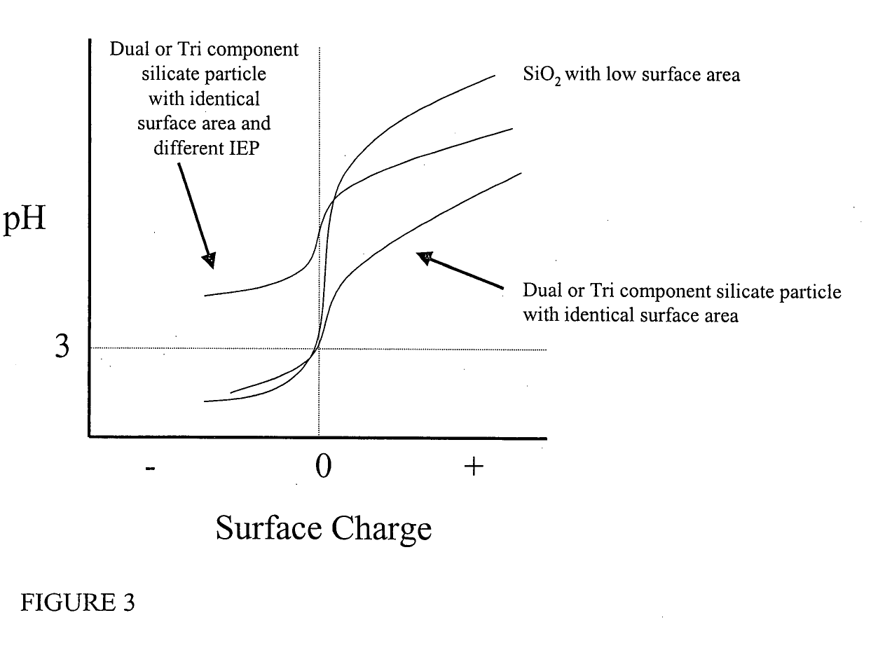

The graph in FIG. 3 illustrates the principle that a multi-component particle exhibits better dispersion performance. The graph shows a comparison of the performance of SiO₂ and multi-component silicate particles of identical particle size. The multi-component particles can have superior dispersion performance at low pH values, and may be tailored to have different isoelectric points. As depicted, the isoelectric point of the multi-component particles is displaced toward a less acidic pH value for better particle dispersion and improved performance in planarization and polishing at an acidic pH value typical for CMP operations.

Accordingly, the present invention provides a CMP manufacturing process for planarizing or polishing metal, semiconductor, dielectric, glass, polymer, optical, and ceramic materials. According to the present invention, abrasive colloidal multi-component particles with a composition comprising mixed 1) metal or metalloid oxides, 2) oxyfluorides, or 3) oxynitrides, each grouping (1, 2, or 3) individually alone or in combination thereof, are employed in a slurry solution. The term “multi-component,” as used herein, refers to a composition having at least two, preferably three or more constituents in a single particle. Variable compositions of the abrasive materials can be used to generate colloidal particles with different surface charges and dispersion behaviors. The surface chemistry of the multi-component particle is modified relative to the surface chemistry performance of the individual, original base constituents of the particles, where in embodiments, the isoelectric point of the particle is displaced toward an alkaline pH value. Each multi-component particle exhibits a modified surface chemistry in which it has an isoelectric point (pH_{IEP}) greater than or equal to about 5-6 with a stabilized particle dispersion at pH values of interest for CMP operations. Preferably, the pK_{IEP} is greater than or equal to about pH 6.5 or 7. This is not to exclude the possibility that one may do the counterpart, in which one fashions particles from compositions with desirable chemical and physical properties that can overcome current dispersion difficulties associated with polishing operations in the range of alkaline pH values.

The composition of abrasive particles may be tailored for desirable chemical or surface properties, necessary to meet particular CMP conditions or parameters. Generally, the multi-component particles are abrasive species that have at least a αₓβ_{y} composition, wherein α is either a transition metal, metalloid, alkaline earth, rare earth, or alkali element, or a plurality combination of transition metal, metalloid, alkaline earth, rare earth, or alkali elements of any desired oxidation level, β is O and/or N, and x and y≠0. An example of a plurality combination is SiAlON.

According to embodiments of the invention, the colloidal abrasives preferably may comprise SiO₂, Al₂O₃, or B₂O₃, in combination with at least one or two other oxides of metals or metalloids. For silicate materials, quantities of glass-formers/modifiers (e.g., Al₂O₃, B₂O₃, CeO₂, GeO₂, P₂O₅, PbO₂, Ta₂O₅, TiO₂, ZrO₂, etc.) can be added to adjust the hardness and surface chemistries of the abrasive particles to produce improved dispersion and stability in planarizing and polishing applications. In some preferred embodiments, the constituents may comprise in weight percent on an oxide basis, about 30-99% SiO₂ and/or 1-37% Al₂O₃ and at least one of the following: 0-70% Li₂O, 0-70% Na₂O, 0-70% K₂O, 0-70% BeO, 0-70% MgO, 0-70% CaO, 0-70% SrO, 0-70% BaO, 0-70% SbO₂, 0-70% SnO₂, 0-70% B₂O₃, 0-70% GeO₂, 0-70% CuO, 0-70% CuO₂, 0-70% P₂O₅, 0-70% PbO₂, 0-70% Ta₂O₅, 0-70% TiO₂, 0-70% CeO₂, 0-70% ZrO₂, and/or 0-20% F, either alone or in combinations thereof. In other embodiments, the mixed-oxide particles include at least three constituents selected from either SiO₂- or Al₂O₃-derivatives doped with metalloid, transition metals, alkali, alkaline earth, or rare earth components, such as described in U.S. patent application Ser. No. 2002/0177311 A1, incorporated herein by reference in its entirety. These may include from the periodic table groups I: preferably Li, Na; IA: preferably K, Rb, Cs; IB: comprising Cu, Ag, Au; II: comprising Be, Mg; IIA: comprising Ca, Sr, Ba, Ra; IIB: comprising Zn, Cd, Hg; III: comprising B, Al; IIIA: comprising Sc, Y, the lanthanides, the actinides; IIIB: comprising Ga, In, TI; IV: preferably Si; IVA: preferably Ti, Zr, Hf; IVB: comprising Ge, Sn, Pb; VA: preferably V, Nb, Ta; VB: comprising As, Sb, Bi; VIA: preferably Cr, Mo, W; VIB: preferably Se, Te; VIIA: preferably Mn, Tc, Re; VIII: preferably Fe, Co, Ni, Ru, Rh, Pd, Os, Ir, Pt. The doped noble metals (Au, Ag, Re, Ru, Rh, Pd, Os, Ir, Pt) are as a rule present in elemental form or also have oxidic surface regions. The oxides of the metals and metalloids of K, Mg, Al, Si, Ti, V, Cr, Mn, Fe, Co, Ni, Cu, Sn, Zn, W, La, Ce and Zr are particularly preferred as the doping component.

For non-silicate-based materials a may be: Al, As, B, Ca, Co, Ce, Cr, Cu, Er, Fe, Ga, Ge, In, K, La, Li, Mg, Mn, Na, Ni, P, Pb, Pr, Rb, Sb, Sn, Ta, Ti, Tl, Tm, V, W, Y, Yb, Zn, and Zr, or combinations of mixed oxides. Further, these colloidal particles may also be doped with rare earth ions or oxides, such as of La, Er, Nd, Pr, Tm, Yb, etc.

Particular compositional examples for the colloidal particles with mixed-oxide components may include: CeO₂—ZrO₂; CeO₂—Al₂O₃; GeO₂—SiO₂; GeO₂—Al₂O₃—SiO₂; Al₂O₃—SiO₂; CaO—Al₂O₃—SiO₂;, P₂O₅—SiO₂, TiO₂—SiO₂, Ta₂O—SiO₂, Sb₂O₃—SiO₂, Sb₂O₃—Al₂O₃-α₂O—SiO₂, wherein α=Li, Na, K, Rb, Cs; βOₐ—Al₂O₃—SiO₂, wherein β=Be, Mg, Ca, Ba, Sr, and a≠0; MgO—Al₂O₃; or such compositions doped with ˜1 or 3-15 wt % F.

TABLE 1

| | | Mean Particle | | Crystal |
|---|---|---|---|---|
| | Composition (wt %) | Size (μm) | Morphology | Phase(s) |
| Example | | | | |
| 1 | 35.5 Al₂O₃, 29.7 CaO, | 0.01-0.02 | Spherical | CaCO₃ |
| | 34.8 SiO₂ | | | |
| 2 | 19.9 Al₂O₃, 10.4 MgO, | 0.02-0.05 | Spherical | None |
| | 69.7 SiO₂ | | | |
| 3 | 6.31 Al₂O₃, 5.9 Sb₂O₃, | <0.01 | Spherical | Al₂O₃ |
| | 86.6 SiO₂ | | | |
| 4 | 12.2 K₂O, 87.8 SiO₂ | 0.15 | near-spherical | SiO₂, KHCO₃ |
| 5 | 0-15 GeO₂ in SiO₂ | 0.1 | Spherical | None |
| 6 | ≦2 F in SiO₂ | 0.1 | Spherical | None |
| Compara. | | | | |
| Example | | | | |
| 1 | 1 Al₂O₃, 99 SiO₂ | <0.01 | Spherical | Al₂O₃ |
| | (Mole %) | | | |
| 2 | 10 Al₂O₃, 90 SiO₂ | <0.01 | Spherical | Al₂O₃ |
| | (Mole %) | | | |
| 3 | Al₂O₃ | 0.1 | Irregular, | Al₂O₃ |
| | | | quasi-spherical | |
| 4 | SiO₂ | 0.1 | Spherical | |

Using various techniques, the abrasive colloidal material can be formed from a variety of components including mixed-oxides or silicate-based glasses, as well as non-glass-forming constituents. Metal or metalloid oxides generated from a pyrogenic process, from a sol-gel process, a hydrothermal process, a plasma process, an aerogel process, a precipitation process or from a combination of these processes are preferred. These processes are described by the example of silicon dioxide in Ullmanns Encyclopedia of Industrial Chemistry, 5th edition, volume A 23, page 583. The mixed-oxide particles may be produced using, for examples, an aerosol combustion process as described in an article by A. Kilian et al., in Aerosol Science and Technology 43:227-235 (2001). Alternatively, the multi-component particles may be made according to a method and apparatus as described in U.S. Pat. No. 6,363,746, the content of which is incorporated herein by reference. The process may employ combustion of a liquid aerosol, and the liquid can be made to contain a large number of components, so the particles prepared can encompass just about any multi-component oxide.

Employing such processes, one is able to make particles of various nanometer-scale sizes wherein each particle has a tailored composition. The BET surface area of the multi-component oxide can be between about 3 and 1000 m²/g, preferably between about 20 and 500 m²/g, more preferably between about 30-200 m²/g. The multi-component particles have an average particle dimension (e.g., diameter) of up to about 500 or 600 nanometers (0.5-0.6 microns), with a distribution having a variable mean particle size of between about 10-400 nm. Preferably the average dimension of each particle may range from about 10 nm to about 200 or 300 nm, more preferably about 25 or 30 nm to about 150 or 180 nm. In contrast to fused silica particles which are much larger, with dimensions of greater than 1 or 5 microns, the silicate-based particles are fumed soot particles, preferably, ranging from about 1 nm to up to about 200 nm, preferably ˜25-150 nm. The resulting particles have either a spherical, near-spherical, elongated, or amorphous (non-crystalline) morphology. Preferably, dendritic, non-spherical, regular or irregular crystalline forms should be avoided.

When applied in a CMP slurry, the particle size distribution may take the form of a single mode distribution, or alternatively, may be a multi-modal distribution as the desired use may dictate. That is, within a slurry mixture, the multi-component particles may have a particle-size distribution with two or more modes each with a mean particle size. The distribution of particle sizes may have a normal (gaussian) distribution or skewed distribution. Although the overall particle size distribution may span the entire range of average particle dimensions (˜1-600 nm), preferably, the variation in particle size is relatively small, such that the size of individual particles is clustered closely round a mean value. For instance, in a single distribution curve the average dimensions of about 68-95% (two standard deviations) of the particles are within about ±30-50 nm (preferably within about ±25 nm) of a mean value. Particle-size distribution can be adjusted to control the final surface finish as well as the ability to clean residue abrasive particles from workpiece surfaces after processing.

The abrasive particles of the present invention may be applied to various material substrates for various uses. The particles may form part of a solution for planarizing or polishing semiconductor, optical, and ceramic materials. The manufacturing processes for devices in semiconductor, optical, telecommunication, and television or visual display industries, however, may particularly benefit from the present invention since these processes typically require to planarized through chemical-mechanical means a workpiece surface. The particles in solution are preferably selected for chemical and physical properties that reduce agglomeration under predetermined pH conditions employed in the planarizing or polishing operations.

For instance in the semiconductor integrated circuit finishing industry, the present abrasive particle materials offer advantages for the fabrication of microelectronic devices, specifically for application to silicon wafers, oxide coating on such wafers, conductive metals used in microelectronic devices (e.g., silica, aluminum, copper, tantalum, tungsten, etc.), and ceramics used in microelectronics (e.g., silicon nitride and silicon carbide). These advantages including (1) relatively small particle size (˜1 nm to ˜200 nm) with spherical or near-spherical morphology and (2) mutli-components for added stabilization over SiO₂ alone. For semiconductor processing, the CMP slurries of multi-component particles preferably provide beneficial film removal rates that are independent of solid-loading (weight % of particles in the slurry). In particular, the slurry can provide removal rates, independent of the level particle solids loading, for metallic copper layer film of greater than 0.5 μm/minute. In the slurry the weight percent levels of particles are in the range of 1 to 10 wt. %, and preferably in the range of 1 to 6 wt. % of particles in the slurry. The inventive CMP slurries preferably provide beneficial semiconductor processing with deposited film removal rates that are ≧0.5 μm/minute, particularly a metallic copper layer film removal rate of at least 0.5 μm/minute.

The particle materials demonstrate four preferred points in specific application to the chemo-mechanical polishing (planarization) of microelectronic materials such as copper, aluminum, tungsten, and silicon as well as related carbides and nitrides. Semiconductor processing CMP slurries incorporating multi-component particles preferably provide planarized surface workpiece finishes with a surface finish of ≦0.6 nm RMS.

First, as compared to conventional pure silica soot, the multi-component doped particles exhibit significantly improved stability and better dispersion properties at low pH levels of less than or equal to about 7, preferably pH of about 5. This feature provides the multi-component-doped particles with beneficial performance when applied in slurry as a polishing compound at pH≦5.

Second, the fact that multi-component doped particles more readily disperse in solution at higher pH values (pH>5 or 7) suggests that the inventive particles would perform in a superior manner for microelectronic applications than conventional undoped fused silica soot, which exhibits greater resistance to dissolution in typical acidic pH range employed for CMP.

Third, the preferred spherical nature and particle sizes of the inventive soot materials suggest that the mechanical performance of the soot materials used as abrasive particles would not scratch the surface being polished.

Fourth, larger-sized multi-component oxide particles with at least three or more constituent oxides or elements may have decreased surface area of ˜10-20 m²/gram, as compared to competing silica particle materials (100-400 m²/gram) such as fumed silica. The particles with less surface area can be dispersed in solution using less dispersion aids, thus eliminating sources of contamination or unwanted levels of dispersion aids used.

With regard to optical components and devices, optical material may comprise glasses or polymer-based materials, such as for the surface of a TV or visual display unit, or planar optical waveguides. In the fabrication of planar lightwave circuits (PLC), one provides an optical cladding and core layer, patterns the optical core layer, and deposits another optical cladding layer over the patterned core. Deposition of the second cladding layer over the patterned core layer can produce variations in the surface topography of the workpiece. Deposition typically is by flame hydrolysis (FHD), plasma enhanced chemical vapor deposition (PECVD), low pressure chemical vapor deposition (LPCVD), atmospheric chemical vapor deposition (APCVD), or RF sputtering. Patterning is performed by photolithography and etching in a reactive ion etcher (RIE). The geometry of the core is typically 7.5×7.5 μm in cross-section to minimize insertion loss by providing a good mode overlap with standard optical fiber. LPCVD and PECVD processes conform to the workpiece surface, thus reproducing the topography of the surface including any surface irregularities or defects, which over successive layers of depositions are magnified. Greatly exaggerated surface topography is often observed in metal hydride-based PECVD. Because of the limited surface mobility of a precursor, growth from the horizontal and vertical surfaces of a guide can be “pinched-off,” leaving a “root crack” defect. FHD and APCVD use a “reflow” or “consolidation” thermal treatment, however, this process does not eliminate irregularities over the patterned guide.

Hence, chemical-mechanical polishing needs to be applied to make the surface more uniformly planar by reducing variations in the typography produced when an optical cladding layer is deposited over a patterned guide. If a further additional photolithography step is required, the surface would need to be planarize to a smoothness of within about one micron tolerance to ensure proper exposure. For example, an additional mask is required for metallization in a thermal optical switch or to make trenches for optical cross-connects.

The CMP requirements for PLC production comprise several steps and variations. Planarizing to within a micron of desired tolerance is sufficient for lithography. A surface roughness less than about 40 nm (by AFM) may be desirable for depositing of an over-cladding layer. Next, the surface needs to be properly cleaned to remove abrasives and minimize changes in film index, expansion, and absorption due to the CMP process. Contamination by abrasive particles can lead to greatly increased surface roughness in any film deposited over the polished layer. Changes in optical properties of the film deposition can decrease optical performance. Tolerances to pH and embedding of abrasives will have to be determined for each composition. Typical compositions for planar light optical circuits (LOC) include a cladding having a composition comprising, in weight percent, about 1.2-5% P₂O₅, 4-5.4% B₂O₃, and the remaining balance of SiO₂; and a SiO₂ core of doped with about 12-24% GeO₂.

The optical materials may include relatively hard glasses such as silicates, borosilicates, boroaluminosilicates, or aluminosilicates, or oxide crystal such as Al₂O₃ (sapphire) and SiO₂ (quartz) crystals. Relatively soft glasses and other optical material can also benefit from the inventive polishing method and multi-component abrasives, such as phosphorous, chalcogenide, chalco-halide (see, J. S. Sanghera et al., J. Non-Cryst. Solids, 103 (1988), 155-178); J. Lucas et al., J. Non-Cryst. Solids 125 (1990), 1-16; and H-L. Ma et al., J. Solid State Chem. 96, 181-191 (1992)), and halide glasses, or fluoride crystals (e.g, LiF, BaF₂, BeF₂, MgF₂, or CaF₂). For waveguide (planar or fiber) applications, particles with similar, if not exactly the same composition as the waveguide material, can be employed. This includes compositions such as an erbium-doped multi-component silicate glass, such as those described in commonly owned and copending U.S. patent application Ser. No. 09/288,454, filed on Apr. 8, 1999.

Alternative kinds of glasses may include chalco-halide glasses. Chalco-halide glasses are similar in composition to the sample chalcogenides except for the addition of Cl, Br, and I. A typical system would be glasses encompassed by the member components As—S—I, where Tg can range from below room temperature for very I-rich species to about 250° C. for I-poor compositions. Similar glasses exist in the systems: As—S, Se—Cl, Br; Ge—S, Se—Cl, Br, I and Ge—As—S, Se—Cl, Br, I, as given in the review paper by.

Another major class of chalco-halide glasses are the so-called TeX or TeXAs glasses, containing Te and a halogen X with or without a crosslinking element such as As. For thermally stable lenses, the TeXAs glasses would be more preferred over the TeX glasses. Typical examples of these and other chalco-halides are presented by J. Lucas and X-H. Zhang, J. Non-Cryst. Solids 125 (1990), 1-16, and H-L. Ma et al., J. Solid State Chem. 96, 181-191 (1992), incorporated herein by reference.

Halide glasses also may be employed for applications according to the present invention. Particular glass examples may be drawn from the wide family of fluorozirconate glasses of which a typical example, referred to as ZBLAN, has a composition in terms of mole percent of about: 53% ZrF₄, 20% BaF₂, 4% LaF₃, 3% AlF₃, 20% NaF, with a Tg of about 257-262° C. Other possible halide glasses include the Cd halides of which the following is a typical example: 17% CdF₂, 33% CdCl₂, 13% BaF₂, 34% NaF, and 3% KF, with a Tg of about 125° C. Broad compositional ranges for these kinds of halide glasses are given in U.S. Pat. No. 5,346,865, incorporated herein, which include: 42-55% CdF2 and/or CdCl2, 30-40% NaF and/or NaCl, 2-20% total of BaF2 and/or BaCl2+KF and/or KCl, with optional halides as listed.

These two illustrative halide glass families are not necessarily fully inclusive of all halides as there are also fluorindate and fluorogallate glasses in which the major constituents are typically alkaline earth fluorides, (e.g., ZnF₂, CdF₂ and InF3 and/or GaF₃). Having Tgs similar to that of ZBLAN, Tgs for these glasses can range from about 260-300° C. A representative example is: 19% SrF₂, 16% BaF₂, 25% ZnF₂, 5% CdF₂, 35% InF₃, with a Tg of 285° C. When molding halide glasses according to the present invention, it is preferred that a non-reactive coating be used with the mold material to prevent the halide species from reacting with air.

All of these glasses and crystals may be made into various optical devices, including a lens, microlens, array of lenses or microlenses, or grating.

The present invention has been described generally and in detail by way of the figures and examples of preferred embodiments. Persons skilled in the art, however, can appreciate that the invention is not limited necessarily to the embodiments specifically disclosed, but that substitutions, modifications, and variations may be made to the present invention and its uses without departing from the scope of the invention. Therefore, changes should be construed as included herein unless they otherwise depart from the scope of the invention as defined by the appended claims and their equivalents.

We claim:

1. A chemical-mechanical manufacturing process for planarizing or polishing semiconductor, metal, dielectric, glass, polymer, optical, and ceramic materials, the process comprising:
a) providing a workpiece;
b) providing a chemical-mechanical planarizing colloidal slurry, said slurry comprising non-agglomerated multi-component particles of a mixed-oxide, oxyfluoride, or oxynitride composition, each particle exhibiting a modified surface chemistry performance and having an isoelectric point (pH_{IEP}) greater than the pH of dispersed particles in solution.
c) abrading a surface of said workpiece with said multi-component particles.

2. The process according to claim 1, wherein said particle surface chemistry is modified relative to the surface chemistry performance of the individual, original base constituents of said mixed-oxide particle.

3. The process according to claim 2, wherein said isoelectric point of said multi-component particle is displaced toward an alkaline pH value relative to the surface chemistry performance of the individual, original base constituents of said particle.

4. The process according to claim 1, wherein said particle has an isoelectric point (pH_{IEP}) greater than or equal to about 5-6 with a stabilized particle dispersion at pH values of interest for CMP operations.

5. The process according to claim 1, wherein said isoelectric point of said multi-component particle is greater than or equal to about pH 7.

6. The process according to claim 1, wherein said multi-component particles have a composition αₓβ_{y}, wherein α is a transition metal, metalloid, alkaline earth, rare earth, or alkali element, or a plurality combination thereof, β is O and/or N, and x and y≠0.

7. The process according to claim 6, wherein SiAlON is a plurality combination.

8. The process according to claim 6, wherein quantities of glass-formers/modifiers comprising Al₂O₃, B₂O₃, CeO₂, GeO₂, P₂O₅, PbO₂, Ta₂O₅, TiO₂, ZrO₂, are added to silicate materials to adjust the surface chemistries and hardness of said particles.

9. The process according to claim 6, wherein for non-silicate-based materials a is selected from: Al, As, B, Ca, Co, Ce, Cr, Cu, Er, Fe, Ga, Ge, In, K, La, Li, Mg, Mn, Na, Ni, P, Pb, Pr, Sb, Sn, Ta, Ti, Tl, Tm, V, W, Y, Yb, Zn, and Zr.

10. The process according to claim 1, wherein said mixed-oxide components include CeO₂—ZrO₂; CeO₂—Al₂O₃; GeO₂—SiO₂; GeO₂—Al₂O₃—SiO₂; Al₂O₃—SiO₂; CaO—Al₂O₃—SiO₂;, P₂O₅—SiO₂, TiO₂—SiO₂, Ta₂O₅—SiO₂, Sb₂O₃—Al₂O₃-α₂O—SiO₂, wherein α=Li, Na, K, Rb, Cs; βOₐ—Al₂O₃—SiO₂, wherein β=Be, Mg, Ca, Ba, Sr, and a ≠0; MgO—Al₂O₃; or such compositions doped with ˜1 or 3-15 wt % F.

11. The process according to claim 1, wherein said abrasive has a multi-component composition comprising a combination of constituents selected from either SiO₂, Al₂O₃, B₂O₃, and at least two or optionally three other oxides.

12. The process according to claim 1, wherein said mixed-oxide particle comprises in weight percent on an oxide basis, about 30-99% SiO₂, 1-37% Al₂O₃ and at least one of the following: 0-70% Li₂O, 0-70% Na₂O, 0-70% K₂O, 0-70% BeO, 0-70% MgO, 0-70% CaO, 0-70% SrO, 0-70% BaO, 0-70% SbO₂, 0-70% SnO₂, 0-70% B₂O₃, 0-70% GeO₂, 0-70% CuO, 0-70% CuO₂, 0-70% P₂O₅, 0-70% PbO₂, 0-70% Ta₂O₅, 0-70% TiO₂, 0-70% CeO₂, 0-70% ZrO₂, and/or 0-20% F, either alone or in combinations thereof.

13. The process according to claim 1, wherein said mixed-oxide particle includes at least three constituents selected from either SiO₂- or Al₂O₃-derivatives doped with metalloid, transition metals, alkali, alkaline earth, or rare earth components.

14. The process according to claim 1, wherein said particles are fumed silicate particles.

15. The process according to claim 1, wherein said multi-component particle has a pre-selected surface chemistry and hardness tailored to said workpiece surface.

16. The process according to claim 1, wherein said multi-component particle has at least two components, and with a particle size in the range of about 1-30 nanometers.

17. The process according to claim 1, wherein said multi-component particle has at least three components, and a particle size in the range of about 1-500 nanometers.

18. The process according to claim 17, wherein said multi-component particle has at least three components, and each with a particle size in the range of about 1-200 nanometers.

19. The process according to claim 1, wherein said multi-component particle has at least three components, and a particle size in the range of about 1-150 nanometers.

20. The process according to claim 19, wherein the size of said multi-component particles range from about 10 nm to up to about 150 nm.

21. The process according to claim 1, wherein said multi-component particles each has either a spherical, near-spherical, elongated, or amorphous morphology.

22. The process according to claim 1, wherein said multi-component particles are formed according to a flame hydrolysis process.

23. The process according to claim 1, wherein said multi-component particles are formed according to a sol-gel process.

24. The process according to claim 1, wherein said multi-component particles are dispersed in either an aqueous or non-aqueous suspension.

25. The process according to claim 1, wherein said multi-component particles are either oxyfluoride or oxynitride compositions.

26. The process according to claim 1, wherein said workpiece has a non-planarized surface.

27. The process according to claim 1, wherein providing a workpiece includes providing a semiconductor integrated circuit workpiece having a metallized interconnection structure.

28. The process according to claim 26, wherein providing a workpiece includes providing a semiconductor integrated circuit silicon wafer with a lithographic integrated circuit pattern and depositing at least one metallized interconnection layer.

29. The process according to claim 1, wherein providing a workpiece includes providing a semiconductor integrated circuit workpiece having an interlevel dielectric structure.

30. The process according to claim 28, wherein providing a workpiece includes depositing an interlevel dielectric material on a semiconductor integrated circuit workpiece.

31. A method for using a CMP slurry solution, the method comprising providing a solution of multi-component particles, said particles having a composition comprising mixed 1) metal or metalloid oxides, 2) oxyfluorides, or 3) oxynitrides, each grouping (1, 2, or 3) individually alone or in combination thereof, said particles exhibiting a modified surface chemistry performance and having an isoelectric point (pH_{IEP}) greater than or equal to about 5-6 with a stabilized particle dispersion at pH values of interest for CMP operations; dispersing said particles in a slurry; and applying said slurry to a workpiece.

32. A CMP slurry solution for planarizing and polishing semiconductor materials, the slurry comprising colloidal particles with a composition comprising mixed 1) metal or metalloid oxides, 2) oxyfluorides, or 3) oxynitrides, each grouping (1, 2, or 3) individually alone or in combination thereof, said particles exhibiting a modified surface chemistry performance and having an isoelectric point (pH_{IEP}) greater than the pH of dispersed particles in solution.

33. The solution according to claim 32, wherein pH_{IEP} is greater than or equal to about 5-6 with a stabilized particle dispersion at pH values of interest for CMP operations.

34. The solution according to claim 32, wherein said CMP operations have a pH value between about 2-4.

35. The solution according to claim 32, wherein said isoelectric point is greater than or equal to about pH 6.5, when said CMP operations have a pH value between about 2-5.

36. The solution according to claim 32, wherein said isoelectric point is greater than or equal to about pH 7, when said CMP operations have a pH value between about 2-6.

37. The solution according to claim 32, wherein said particles have a mixed-oxide composition of either: (a) at least two metal-oxide components with a particle size in the range of about 1-30 nanometers, (b) at least three components with a particle size in the range of about 1-500 nanometers, or (c) a combination of (a) and (b), wherein said particle chemistry agglomeration resistant upon dispersion under predetermined pH conditions as employed in said planarizing or polishing operations, dispersed in a semiconductor processing slurry solvent.

38. The solution according to claim 32, wherein said colloidal particles are multi-component, mixed-oxide particles, each exhibiting a modified surface chemistry performance and having an isoelectric point (pH_{IEP}) greater than or equal to about 6 with a reduced tendency to agglomerate at pH values of interest for CMP operations.

39. The solution according to claim 32, wherein said multi-component particles are either oxyfluoride or oxynitride compositions.

40. The solution according to claim 32, wherein said semiconductor materials include: single crystal silicon, metals, dielectric materials, and metal oxides.

41. The solution according to claim 32, wherein said semiconductor metal materials include an integrated circuit film of: aluminum alloy, copper, nickle, tungsten, tungsten silicide, titanium, titanium nitride, tantalum, tantalum nitride, or Ta₂O₅.

42. The solution according to claim 32, wherein said semiconductor processing slurry is an aqueous solvent.

43. The solution according to claim 32, wherein said semiconductor processing slurry is a non-aqueous solvent.

44. The solution according to claim 32, wherein the CMP slurry provides film removal rates, independent of solid-loading, that are greater than about 0.5 μm/minute for metallic copper layer.

45. The solution according to claim 44, wherein the solution has a solid-loading with weight percent level in the range of about 1 to 10 wt. %.

46. The solution according to claim 45, wherein the solution has a solid-loading with weight percent level in the range of about 1 to 6 wt. %.

47. A CMP slurry solution for planarizing and polishing optical materials, the slurry comprising colloidal particles with a composition comprising mixed 1) metal or metalloid oxides, 2) oxyfluorides, or 3) oxynitrides, each grouping (1, 2, or 3) individually alone or in combination thereof, said particles exhibiting a modified surface chemistry performance and having an isoelectric point (pH_{IEP}) greater than the pH of dispersed particles in solution.

48. The solution according to claim 47, wherein said pH_{IEP} is greater than or equal to about 5-6 with a stabilized particle dispersion at pH values of interest for CMP operations.

49. The solution according to claim 47, wherein said particles have a mixed-oxide composition of either: (a) at least two metal-oxide components with a particle size in the range of about 1-30 nanometers, (b) at least three components with a particle size in the range of about 1-500 nanometers, or (c) a combination of (a) and (b), wherein said particle chemistry is agglomeration resistant upon dispersion under predetermined pH conditions as employed in said planarizing or polishing operations.

50. The solution according to claim 47, wherein said colloidal particles are multi-component, mixed-oxide particles, each exhibiting a modified surface chemistry performance and having an isoelectric point (pH_{IEP}) greater than or equal to about 6 with a reduced tendency to agglomerate at pH values of interest for CMP operations.

51. The solution according to claim 47, wherein said isoelectric point is greater than or equal to about pH 7.

52. The solution according to claim 47, wherein said optical materials comprise a glass, a metallic oxide crystal, a fluoride crystal, and a polymer-based material.

53. The solution according,to claim 52, wherein said glass includes silicates, borosilicates, boroaluminosilicates, aluminosilicates, chalcogenides, chalco-halides, and halides.

54. The solution according to claim 52, wherein said oxide crystal includes Al₂O₃ (sapphire) and SiO₂ (quartz) crystals.

55. The solution according to claim 52, wherein said fluoride crystal includes LiF, BeF₂, MgF₂, CaF₂, SrF₂, and BaF₂.

56. The solution according to claim 47, wherein said optical material comprises a surface of a visual display unit.

57. The solution according to claim 47, wherein said optical material comprises a lens, microlens, array of lenses or microlenses, or grating.

58. The solution according to claim 47, wherein said optical material comprises an optical waveguide.

59. The solution according to claim 47, wherein said particles are dispersed in an aqueous solvent.

60. The solution according to claim 47, wherein said particles are dispersed in a non-aqueous solvent.

61. The solution according to claim 47, wherein said multi-component colloidal particles have a composition of mixed-oxides, in weight percent, comprising about: 30-99% SiO₂, 1-37% Al₂O₃, and at least one of the following: 0-70% Li₂O, 0-70% Na₂O, 0-70% K₂O, 0-70% BeO, 0-70% MgO, 0-70% CaO, 0-70% SrO, 0-70% BaO, 0-70% SbO₂, 0-70% SnO₂, 0-70% B₂O₃, 0-70% GeO₂, 0-70% CuO, 0-70% CuO₂, 0-70% P₂O₅, 0-70% PbO₂, 0-70% Ta₂O₅, 0-70% TiO₂, 0-70% CeO₂, 0-70% ZrO₂, and/or 0-20% F, either alone or in combinations thereof.

62. The solution according to claim 47, wherein said multi-component particles are either oxyfluoride or oxynitride compositions.

63. The solution according to claim 47, wherein said multi-component particles each has either a spherical, near-spherical, elongated, or amorphous (non-crystalline) morphology.

64. The solution according to claim 47, wherein said multi-component particles have an average dimension ranging from about 1 nm to about 150 nm.

65. The solution according to claim 47, wherein said multi-component particles, in solution, exhibit stable dispersion performance, without agglomerating to each other, at pH values <5.
